(19) United States
(12) Patent Application Publication
(10) Pub. No.: US 2022/0167531 A1
(43) Pub. Date: May 26, 2022

(54) NETWORK ADAPTER AND NETWORKING DEVICE

(71) Applicant: BOE Technology Group Co., Ltd., Beijing (CN)

(72) Inventor: Jinggang WEI, Beijing (CN)

(21) Appl. No.: 17/526,675

(22) Filed: Nov. 15, 2021

(30) Foreign Application Priority Data
Nov. 20, 2020 (CN) 202022705525.9

(51) Int. Cl. H05K 7/20; H05K 5/04

(52) U.S. Cl. CPC H05K 7/20409; H05K 5/04

(57) ABSTRACT

Provided is a network adapter. The network adapter includes a housing, a communication module, and a thermally conductive member. The housing is provided with a mounting chamber; the communication module and the thermally conductive member are both disposed in the mounting chamber; the housing includes a metal portion, wherein the metal portion extends from an inner side surface of the housing to an outer side surface of the housing; and the thermally conductive member is in thermal contact with both the communication module and the metal portion. With such a design, the thermally conductive member guides and conducts the heat generated in the operating process of the communication module to the metal portion, and heat dissipation is achieved by the metal portion.

### CROSS-REFERENCE TO RELATED APPLICATION

This application is based on and claims priority to Chinese Patent Application No. 202022705525.9, filed on Nov. 20, 2020 and entitled “NETWORK ADAPTER AND TERMINAL DEVICE,” the disclosure of which is herein incorporated by reference in its entirety.

### TECHNICAL FIELD

The present disclosure relates to the field of communication device technologies, and in particular, relates to a network adapter and a networking device.

### BACKGROUND

A network adapter is configured for a terminal device to access a network. With the development of communication technologies, the amount of data to be processed by the network adapter is relatively large, and the power consumption is relatively large, resulting in a relatively large amount of heat.

### SUMMARY

Embodiments of the present disclosure provide a network adapter and a networking device.

In a first aspect of the embodiments of the present disclosure, a network adapter is provided. The network adapter includes a housing, a communication module, and a thermally conductive member. The housing is provided with a mounting chamber. The communication module and the thermally conductive member are both disposed in the mounting chamber. The housing includes a metal portion, wherein the metal portion extends from an inner side surface of the housing to an outer side surface of the housing. The thermally conductive member is in thermal contact with both the communication module and the metal portion.

In some embodiments, the housing includes a base and a cover plate, wherein the cover plate is connected to the base to define the mounting chamber, the cover plate is the metal portion, and the base is a plastic base or a metal base.

In some embodiments, the thermally conductive member is a thermally conductive silicone pad, wherein one side surface of the thermally conductive silicone pad is in contact with the communication module, and the other side surface of the thermally conductive silicone pad is in contact with the cover plate.

In some embodiments; the network adapter further includes a plurality of heat-dissipation fins, wherein the plurality of heat-dissipation fins are disposed on an outer side surface of the metal portion, and the outer side surface of the metal portion is a surface, distal from the mounting chamber, of the metal portion.

In some embodiments, the plurality of heat-dissipation fins are disposed side by side along a first side-by-side direction, and at least one of the plurality of heat-dissipation tins is provided with a first limiting protrusion; wherein the first limiting protrusion protrudes outward from the heat-dissipation fins where the first limiting protrusion is disposed along the first side-by-side direction, and a gap is present between the first limiting protrusion and the outer side surface, disposed between the adjacent heat-dissipation fins, of the metal portion.

In some embodiments, the network adapter further includes an elastic protrusion; wherein the elastic protrusion is connected to the housing, and is configured to extend into a positioning hole of the terminal device in the case that the network adapter slides to an assembling position relative to the terminal device, so as to prevent the network adapter from further sliding.

In some embodiments, an end portion, proximal to the positioning hole, of the elastic protrusion is provided with an inclined surface; wherein the inclined surface is configured to be matched with the positioning hole to push the elastic protrusion to detach from the positioning hole in a sliding process of the network adapter relative to the terminal device.

In some embodiments, the elastic protrusion includes a mounting seat, a positioning column, and an elastic member; wherein the mounting seat is connected to a side wall of the mounting chamber; one end of the positioning column is movably connected to the mounting seat; and the other end of the positioning column is provided with the inclined surface and is disposed outside the mounting chamber; and the elastic member is disposed between the positioning column and the mounting seat along a telescopic direction of the positioning column.

In some embodiments, the network adapter further includes at least one communication antenna; wherein the communication antenna is connected to the communication module, and the communication antenna is disposed inside the mounting chamber or outside the mounting chamber.

In some embodiments, the communication module is at least a 4G module or a 5G module.

In some embodiments, the network adapter further includes a network transmission device and a circuit board; wherein the communication module and the network transmission device are both connected to the circuit board; and the network transmission device and the circuit board are disposed in the mounting chamber.

In some embodiments, the housing is provided with a network opening, and the network transmission device includes a network interface, wherein the network interface is exposed from the network opening.

In a second aspect of the embodiments of the present disclosure, a networking device is provided. The networking device includes a terminal device and a network adapter. The terminal device is configured to be networked via the network adapter. The terminal device includes a metal shell; and the network adapter includes: a housing, a communication module, and a thermally conductive member. The housing is provided with a mounting chamber, and the communication module and the thermally conductive member are both disposed in the mounting chamber. The housing includes a metal portion, wherein the metal portion extends from an inner side surface of the housing to an outer side surface of the housing, and the thermally conductive member is in thermal contact with both the communication module and the metal portion; and the housing is connected to the metal shell, and the metal portion is in contact with the metal shell.

In some embodiments, the housing includes a base and a cover plate; wherein the cover plate is connected to the base to define the mounting chamber, the cover plate is the metal portion, and the base is a plastic base or a metal base.

In some embodiments, the network adapter further includes a plurality of heat-dissipation fins, wherein the plurality of heat-dissipation fins are disposed on an outer side surface, distal from the mounting chamber, of the metal portion and are disposed side by side along a first side-by-side direction; and the metal shell is provided with a plurality of matching teeth disposed side by side; wherein the plurality of matching teeth extend into a lateral side region of the plurality of heat-dissipation fins along the first side-by-side direction, and the plurality of heart-dissipation fins and opposite side surfaces of the plurality of matching teeth are matched in a contact fashion.

In some embodiments, at least one of the plurality of heat-dissipation fins is provided with a first limiting protrusion; wherein the first limiting protrusion protrudes outward from the heat-dissipation fins where the first limiting protrusion is disposed along the first side-by-side direction, and a gap is present between the first limiting protrusion and the outer side surface, disposed between the adjacent heat-dissipation fins, of the metal portion; and each of the matching teeth is provided with a second limiting protrusion; wherein the second limiting protrusion and the first limiting protrusion are matched with each other to avoid detaching between the matching teeth and the heat-dissipation fins.

In some embodiments, the matching tooth is made of an aluminum profile.

In some embodiments, a positioning hole is disposed in an outer side wall of the metal shell, and the network adapter further includes an elastic protrusion, wherein the elastic protrusion is configured to extend into the positioning hole in the case that the network adapter slides to an assembling position to prevent the network adapter from further sliding.

In some embodiments, the elastic protrusion includes a mounting seat, a positioning column, and an elastic member wherein the mounting seat is connected to a side wall of the mounting chamber; one end of the positioning column is movably connected to the mounting seat, and the other end of the positioning column is provided with an inclined surface and is disposed outside the mounting chamber; and the elastic member is disposed between the positioning column and the mounting seat along a telescopic direction of the positioning column.

In some embodiments, the terminal device is a display device, the display device includes a display screen and a metal shell; wherein the metal shell includes a display frame disposed on a periphery of the display screen and a back cover disposed on a back of the display screen, and the network adapter is disposed at the display frame or the back cover.

### BRIEF DESCRIPTION OF THE DRAWINGS

For clearer descriptions of the technical solutions in the embodiments of the present disclosure or in the related art, the following briefly introduces the accompanying drawings required for describing the embodiments or the related art. Apparently, the accompanying drawings in the following description show merely some embodiments of the present disclosure, and persons of ordinary skill in the art may still derive other accompanying drawings from these accompanying drawings without creative efforts.

FIG. 1 is an exploded view of a network adapter according to an embodiment of the present disclosure;

FIG. 2 is a schematic assembling structural diagram of the network adapter shown in FIG. 1;

FIG. 3 is a partially enlarged schematic structural diagram of a cover plate in FIG. 1 and FIG. 2;

FIG. 4 is a matching schematic diagram of a network adapter and a display device according to an embodiment of the disclosure;

FIG. 5 is a schematic structural diagram of a network adapter and a display device in a matching position according to an embodiment of the disclosure; and

FIG. 6 is a schematic diagram of a matching relationship between an elastic protrusion on a network adapter and a positioning hole on a shell of a display device.

### DETAILED DESCRIPTION

For clearer descriptions of the objects, technical solutions, and advantages of the embodiments of present disclosure, the technical solutions of the embodiments of the present disclosure are described clearly and completely hereinafter in combination with the accompanying drawings in the embodiments of the present disclosure. It is obvious that the described embodiments are merely part but not all of the embodiments of the present disclosure. All other embodiments obtained by those skilled in the art without creative efforts based on the embodiments in the present disclosure are within the protection scope of the disclosure.

A 5G (that is, 5th generation wireless system or 5th-Generation) wireless network card, also called 5G DONGLE, is a network adapter for a 5G mobile communication network, and is configured to access a 5G network and transmit an accessed 5G network signal to a corresponding communication interface. A terminal device to be networked may realize 5G networking by connection to the communication interface.

The 5G DONGLE facilitates 5G networking of a terminal device incompatible with a 5G Internet access function, or a terminal device incapable of accessing a broadband network. Due to the larger amount of data processed by the 5G DONGLE, the power consumption is larger, resulting in a large amount of heat. In addition, as the 5G DONGLE usually has a small size, a heat dissipation effect is poor, which exacerbates the heating problem of the 5G DONGLE and affects normal use and service life of the 5G DONGLE. The same problem exists in the DONGLE of subsequent evolution networks of 5G (for example, 6G).

Therefore, the network adapter according to the embodiments of the present disclosure includes, but not limited to, a 4G DONGLE, the 5G DONGLE, and the DONGLE of the subsequent evolution networks of 5G.

Hence, the embodiments of the present disclosure provide a network adapter. The network adapter includes a housing, a communication module, and a thermally conductive member. The housing is provided with a mounting chamber, and the communication module and the thermally conductive member are both disposed in the mounting chamber. The housing includes a metal portion, wherein the metal portion extends from an inner side surface of the housing to an outer side surface of the housing, and the thermally conductive member is in thermal contact with both the communication module and the metal portion.

In some embodiments, the thermally conductive member is in contact with both the communication module and the metal portion, and the metal portion extends from the inner side surface of the housing to the outer side surface of the housing. In this way, the heat of the communication module can be quickly transferred to the metal portion through the thermally conductive member, and then transferred to the outside of the housing through the metal portion, which is conducive to improving a heat dissipation efficiency of the network adapter.

Herein, the inner side surface of the housing is a cavity wall of the mounting chamber.

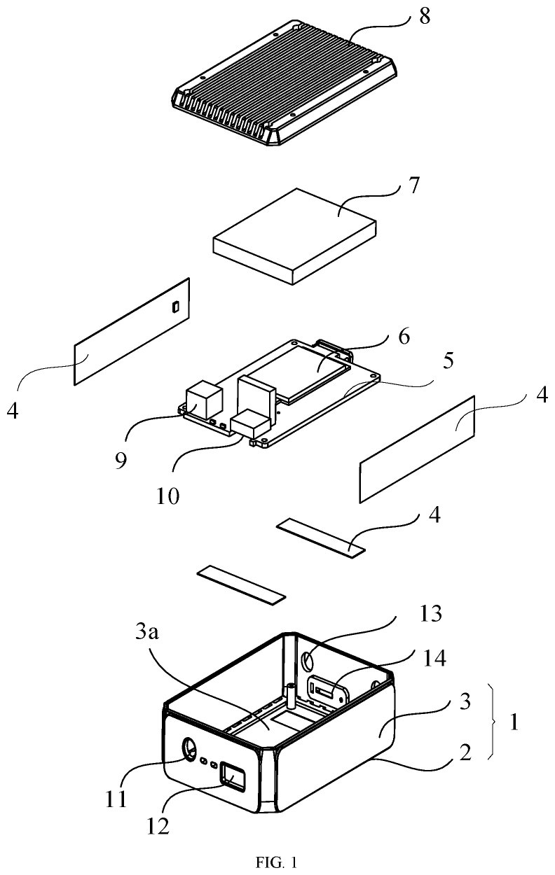

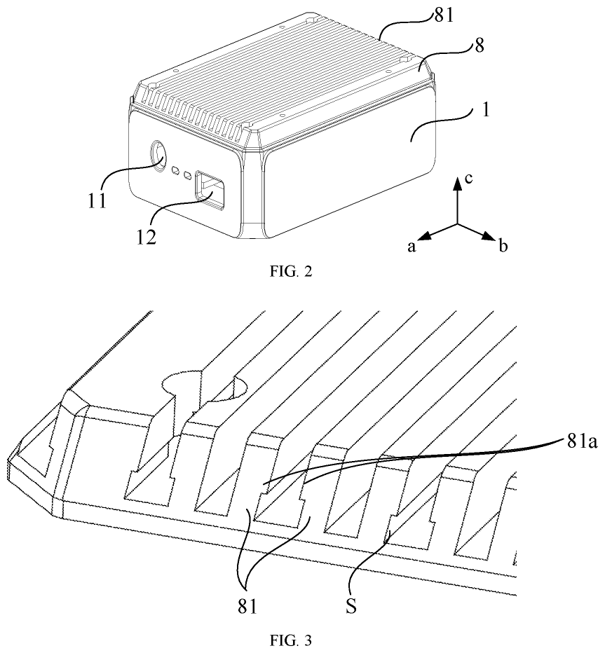

FIG. 1 is an exploded view of a network adapter according to an embodiment of the present disclosure. FIG. 2 is a schematic assembling structural diagram of the network adapter shown in FIG. 1. As shown in FIG. 1, the network adapter includes a housing, a circuit board 5, a communication module 6, a communication interface 10, a communication antenna 4, and a thermally conductive member 7.

Illustratively, the housing is a cuboid box structure. The housing includes a base 1 and a cover plate 8. The base 1 includes a bottom plate 2 and four side plates 3 vertically disposed on a same side surface of the bottom plate 2. The bottom plate 2 is a rectangular plate, and the four side plates 3 are respectively disposed on four lateral sides of the rectangular plate and extend along the lateral sides. The four side plates 3 extending along the corresponding lateral sides are connected into a closed structure. The distances between the lateral sides, distal from the bottom plate 2, of the four side plates 3 and the bottom plate 2 are equal, that is, the four side plates 3 have the same height relative to the bottom plate 2. The bottom plate 2 and the four side plates 3 enclose to form a mounting chamber 3a that is provided with a mounting opening. The mounting opening is defined by lateral side edges, distal from the bottom plate 2, of the four side plates 3, and the mounting chamber 3a is communicated with the outside through the mounting opening.

The cover plate 8 is a rectangular plate connected to the base 1 and covering the mounting opening. During assembling, peripheral edges of the cover plate 8 are in contact with edges, distal from the bottom plate 2, of the side plates 3.

In the above housing, the base 1 is made of a plastic material without affecting a communication signal, for example, acrylonitrile butadiene styrene (ABS) plastic, thereby facilitating arrangement of the built-in communication antenna 4. The cover plate 8 is made of a metal material with a higher thermal conductivity, such as aluminum and copper, thereby facilitating thermal conduction and heat dissipation.

The circuit board 5, the communication module 6, a network transmission device 10, and the communication antenna 4 are disposed in the mounting chamber 3a of the housing, and the circuit board 5 is parallel to the bottom plate 2. The communication antenna 4 is connected to the communication module 6, and the communication module 6 and the network transmission device 10 are connected to the circuit board 5. The communication module 6 is a device for accessing a mobile communication network, for example, may be a 3G module, a 4G module, a 5G module, or the like.

Herein, the 5G module is taken as an example of the communication module for description. The 5G module 6 is connected to the communication antenna 4, and is accessed to the 5G mobile network through the communication antenna 4. In the present embodiment, four communication antennas 4 are disposed. The four communication antennas 4 may be disposed on inner sides of the side plates 3 in a fitting fashion, and disposed on side surfaces, opposite to the circuit board 5, of the base plate 2 in a fitting fashion. Due to the plurality of communication antennas 4, a network connection quality can be improved.

The circuit board 5 is further provided with a processing chip. The 5G module 6 receives a mobile network signal and sends the mobile network signal to the processing chip, the processing chip outputs the mobile network signal to the network transmission device 10, and the terminal device to be networked is connected to the network transmission device 10 to realize 5G networking of the terminal device.

In some embodiments, the communication interface 10 may be an Ethernet interface, such as an RJ-45 interface, an RJ-11 interface, an SC optical fiber interface, a fiber distributed data interface (FDDI), an attachment unit interface (AUI), a BNC interface or a Console interface, and the network transmission device 10 may further be a universal serial bus (USB) interface. The terminal device may be connected to the network transmission device 10 through a corresponding connection cable to realize networking.

In some embodiments, the network transmission device 10 may further include a wireless network card capable of wirelessly transmitting a network signal, and the terminal device is connected to the network transmission device 10 by means of wireless communication, such that the terminal device realizes networking through the network transmission device 10.

The processing chip converts the mobile network signal received by the communication module 6 into network data with a corresponding type to the network transmission device 10, and outputs the network data to the network transmission device 10.

Illustratively, one side plate 3 of the four side plates 3 is provided with a power supply opening 11 and a network opening 12, and another side plate 3 is provided with a card slot opening 13. In some embodiments, a heat dissipation hole is further disposed on the base 1. The power supply opening 11, the network opening 12, the card slot opening 13, and a heat dissipation hole all penetrate through the base 1 to be communicated with the mounting chamber 3a.

The circuit board 5 is further provided with a power supply connector 9, and the power supply connector 9 is configured to introduce a power supply for normal operation of the network adapter. The 5G module includes a card slot for accommodating a subscriber identity module (SIM) card. In the case that the circuit board 5 is disposed within the mounting chamber 3a, the power supply connector 9 on the circuit board 5 is aligned with the power supply opening 11, and is exposed from the power supply opening 11, thereby facilitating connection to the power supply. The network transmission device 10 is aligned with the network opening 12 and is exposed from the network opening 12, thereby facilitating the connection between the terminal device and the network transmission device 10. The card slot for accommodating the SIM card is aligned with a card slot opening 14 and is exposed from the card slot opening 14. With such a design, a user can conveniently disassemble and assemble the SIM card outside without opening the housing.

The housing is further provided with the thermally conductive member 7 in a region between the circuit board 5 and the cover plate 8, and the thermally conductive member 7 is a thermally conductive silicone pad disposed between the circuit board 5 and the cover plate 8. Illustratively, the thermally conductive silicone pad is a square pad made of thermally conductive silicone. One side surface of the thermally conductive silicone pad is in thermal contact with the circuit board 5 and the communication module 6 on the circuit board 5, and is capable of conducting the heat generated in the operating process of the circuit board 5 and the communication module 6 to the thermally conductive silicone pad. The other side surface of the thermally conductive silicone pad is in thermal contact with the cover plate 8 and is capable of conducting the heat to the cover plate 8. Here, the thermal contact may be actual contact or non-actual contact, for example, heat transfer is realized by means of thermal radiation.

As the cover plate 8 is made of a metal material with a higher thermal conductivity, the heat in the thermally conductive silicone pad may be conducted to the cover plate 8, and the heat is dissipated through the cover plate 8, thereby improving the heat dissipation efficiency of the network adapter 14, avoiding the influence of excessively high temperature on normal use of the network adapter, improving use stability of the network adapter 14, and ensuring a service life of the network adapter.

The thermally conductive member in the present embodiments is not limited to this. For example, as the data processed by the 5G module is relatively massive, the power consumption is higher, the thermally conductive member should merely be capable of conducting the heat generated by the 5G module, that is, a side surface of the thermally conductive member may merely be in thermal contact with the 5G module. For another example, the thermally conductive member may further be a thermally conductive tape, a thermally conductive gasket, and the like in structure. In addition, a material of the thermally conductive member may be an organic polymer material or a metal material with a larger thermal conductivity, as long as the heat can be conducted to the cover plate 8.

In the above embodiment, the cover plate 8 is the metal portion made of a metal material. However, in other embodiments, the metal portion may be a part of the base 1 or the cover plate 8. In order to accommodate signal transmission of the built-in communication antenna 4, the base 1 is a plastic base. In other embodiments, the network adapter may further adopt an external antenna. During practice of the external antenna, the entire housing may adopt a metal structure, and such a design can further improve the heat dissipation performance of the network adapter 14.

As shown in FIG. 2, in the present embodiment, a plurality of heat-dissipation fins 81 are disposed on an outer side surface, distal from the mounting chamber, of the cover plate 8, and the plurality of heat-dissipation fins 81 are vertically disposed on the outer side surface of the cover plate 8, and are disposed side by side on the outer side surface. Here, an extension direction of an intersection line between the plurality of heat-dissipation fins 81 and the outer side surface is defined as a first length direction a, an arrangement direction of the plurality of heat-dissipation fins 81 is defined as a first side-by-side direction b, and a direction perpendicular to the outer side surface is defined as a first height direction c. In the present embodiment, by disposing the plurality of heat-dissipation fins 81 on the outer side surface of the cover plate 8, a heat dissipation area of the cover plate 8 may be increased, and the heat dissipation efficiency of the cover plate 8 is favorably improved, thereby avoiding the influence of excessively high temperature on normal use of the network adapter, improving the use stability of the network adapter, and ensuring the service life of the network adapter.

In the embodiment shown in FIG. 1, the plurality of heat-dissipation fins 81 are evenly distributed on the entire outer side surface of the cover plate 8. For example, the minimum distance between any two adjacent heat-dissipation fins 81 is equal.

FIG. 3 is a partially enlarged schematic structural diagram of the cover plate in FIG. 1 and FIG. 2. As shown in FIG. 3, at least one of the plurality of heat dissipation teeth 81 (for example, each of the heat-dissipation fins 81 in FIG. 3) is provided with a first limiting protrusion 81a. The first limiting protrusion 81a protrudes outward from the at least one of the plurality of heat-dissipation fins 81 along the first side-by-side direction a, and a gap S is present between the first limiting protrusion 81a and the outer side surface, disposed between the adjacent heat-dissipation fins 81, of the cover plate 8.

Illustratively, at least part of the plurality of heat-dissipation fins 81 on the cover plate 8 are arranged in pairs, and the first limiting protrusions 81a of each pair of heat-dissipation fins 81 extend along directions away from each other. For example, in each pair of heat-dissipation fins 81, the first limiting protrusion 81a of the left heat heat-dissipation fin 81 extends to the left, and the first limiting protrusion 81a of the right heat-dissipation fin 81 extends to the right.

In some embodiments, the cover plate 8 is further provided with an elastic protrusion 82, and by disposing the elastic protrusion 82 and the first limiting protrusion 81a, it is convenient to match the network adapter and the terminal device. This part is described hereinafter in combination with the terminal device.

An embodiment of the present disclosure further provides a terminal device, the network adapter is disposed at the terminal device, and the terminal device realizes networking (for example, 5G networking) through the network adapter.

An embodiment of the present disclosure further provides a networking device, the networking device includes a terminal device and a network adapter, and the terminal device is networked through the network adapter. The terminal device includes a metal shell. The network adapter is any one of the aforementioned network adapters. A housing of the network adapter is connected to the metal shell, and a metal portion of the housing of the network adapter is in contact with the metal shell.

In some embodiments, the terminal device may be a display device such as a smart TV, an all-in-one touch machine, or a conference tablet, or may be any device that needs to be networked, such as a computer. In the present embodiment, the display device is taken as an example for description.

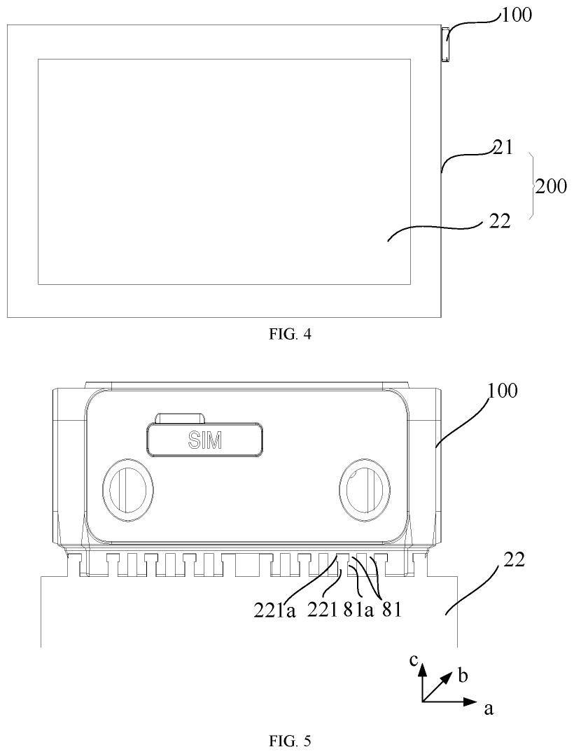

FIG. 4 is a matching schematic diagram of a network adapter and a display device according to an embodiment of the disclosure. As shown in FIG. 4, the display device 200 includes a display screen 21 and a metal shell. The metal shell includes a display frame 22. The display frame 22 surrounds a periphery of the display screen 21, and the network adapter 100 is disposed at the display frame 22. The network adapter 100 may be disposed at any position of the display frame 22. For example, in the embodiment shown in FIG. 4, the network adapter 100 is disposed on the display frame 22 at the upper right side of the display device 200.

FIG. 5 is a schematic structural diagram of a network adapter and a display device in a matching position according to an embodiment of the disclosure. FIG. 5 may be viewed from above or below FIG. 4. As shown in FIG. 5, the display frame 22 is provided with a first connection portion, the network adapter 100 is provided with a second connection portion. The network adapter 100 is disposed at the display device 200 by means of the first connection portion and the second connection portion. The metal portion in the disposed network adapter 100 is in thermal contact with the display frame 22.

With such a design, the heat generated by the network adapter 100 can be conducted to the display frame 22, and heat dissipation is further performed by the display frame 22. As the display frame 22 is a metal structure with a heat dissipation area much larger than a heat dissipation area of the metal portion, the heat dissipation by the display frame 22 is beneficial to improve the heat dissipation efficiency of the network adapter 100.

The display frame 22 includes a contact portion in thermal contact with the metal portion. In an embodiment where the outer side surface of the metal portion is a plane, the contact portion may be a boss that protrudes outward relative to the display frame 22, a top surface of the boss is in contact with the metal portion, and the contact portion may further be part of the structure in the display frame 22.

In an embodiment where the plurality of heat-dissipation fins 81 are disposed on the outer side surface of the metal portion, the display frame 22 is provided with matching teeth 221 matched with the plurality of heat-dissipation fins 81. It is defined that upon the network adapter 100 is disposed at the display device 200, positions, corresponding to the network adapter 100, of the display frame 22 are assembling positions. The display frame 22 is provided with the plurality of matching teeth 221 in the assembling positions, the plurality of matching teeth 221 are vertically disposed on a frame side surface of the display frame 22, and the plurality of matching teeth 221 are disposed side by side on the frame side surface.

Herein, an extension direction of an intersection line between the plurality of matching teeth 221 and the frame side surface is defined as a second length direction, a direction between the plurality of matching teeth 221 side by side is a second side-by-side direction, and a direction perpendicular to the frame side surface is a second height direction. It is understandable that the plurality of matching teeth 221 are parallel to the second length direction and the second height direction, and are perpendicular to the second side-by-side direction.

In the case that the network adapter 100 is connected to the display device 200, the plurality of heat-dissipation fins 81 are matched with the plurality of matching teeth 221 in a staggered fashion, the plurality of matching teeth 221 extend into a lateral side region of the plurality of heat-dissipation fins 81 along the first side-by-side direction a, and the plurality of heat-dissipation fins 81 and opposite side surfaces of the plurality of matching teeth 221 are matched in a contact fashion. Among the plurality of heat-dissipation fins 81 and the plurality of matching teeth 221 which are matched in a staggered fashion, the first length direction b is parallel to the second length direction, the first side-by-side direction a is parallel to the second side-by-side direction, and the first height direction c is parallel to the second height direction.

With such a design, the heat in the cover plate 8 may be conducted to the display frame 22 by the plurality of heat-dissipation fins 81 and the plurality of matching teeth 221 by matching the plurality of heat-dissipation fins 81 and the plurality of matching teeth 221, and a contact area between the network adapter 100 and the display device 200 may be increased, thereby improving the thermally conductive efficiency between the network adapter 100 and the display device 200, such that further heat dissipation is achieved for the network adapter by the display frame 22. In this way, the heat dissipation efficiency of the network adapter 100 is improved.

The network adapter 100 may be disposed at the display device 200 by means of the plurality of heat-dissipation fins 81 and the plurality of matching teeth 221, that is, the matching plurality of teeth 221 are the first connection portion, and the plurality of heat-dissipation fins 81 are the second connection portion. In some embodiments, the plurality of heat-dissipation fins 81 and the plurality of matching teeth 221 which are adjacent are in elastic pressing contact, and the mounting and connection of the network adapter 100 and the display device 200 are realized by a friction force generated by mutual pressing. For example, in FIG. 5, each pair of heat-dissipation fins 81 is disposed between two adjacent matching teeth 221, and the two adjacent matching teeth 221 apply an action force along the first side-by-side direction a to the pair of heat-dissipation fins 81 therebetween, such that the plurality of heat-dissipation fins 81 and the plurality of matching teeth 221 which are adjacent are in elastic pressing contact.

In some embodiments, the two adjacent matching teeth 221 define a mounting chute slidably matched with the plurality of heat-dissipation fins 81, and a length direction of the mounting chute is parallel to the second length direction. During mounting, the plurality of heat-dissipation fins 81 may slide into the mounting chute from an end of the mounting chute along the length direction.

Corresponding to the first limiting protrusion 81a, each of the matching teeth 221 is provided with a second limiting protrusion 221a, the second limiting protrusion 221a protrudes outward from the matching tooth 221 where the second limiting protrusion 221a is disposed along the second side-by-side direction. In the case that the heat-dissipation fins 81 slides into the mounting chute between the plurality of matching teeth 221, the second limiting protrusion 221a is matched with the first limiting protrusion 81a to prevent the matching teeth 221 from detaching from the heat-dissipation fins 81, thereby ensuring the matching reliability between the plurality of matching teeth 221 and the plurality of heat-dissipation fins 81. In this way, the network adapter 100 is slidably disposed on the display device 200.

The first limiting protrusion and the second limiting protrusion have different implementations corresponding to different matching fashions between the network adapter 100 and the display device 200. For example, in the embodiment shown in FIG. 4, the network adapter 100 is disposed at the right display frame 22 of the display device 200, and the right display frame 22 is disposed at a position close to the top. The first length direction and the second length direction are both vertical directions, the mounting chute extends vertically, and the mounting chute includes an upper opening and a lower opening which are disposed at both ends along the length direction, and a top opening opposite to the display frame 22. The heat-dissipation fins 81 slide into the mounting chute from the upper opening of the mounting chute, and the first limiting protrusion 81a and the second limiting protrusion 82a are matched with each other to prevent the heat-dissipation fins 81 from detaching from the matching teeth 221 from the lower opening and the top opening of the mounting chute.

Both the plurality of matching teeth 221 and the plurality of heat-dissipation fins 81 may be extruded from an aluminum profile through an extrusion die, that is, the plurality of matching teeth 221 and the plurality of heat-dissipation fins 81 may both be an aluminum extrusion structure, which is not limited in the embodiments of present application, for example, a machining process of the plurality of matching teeth 221 and the plurality of heat-dissipation fins 81 may be cutting, stamping, casting and other processes, and the material may be a metal material with a high thermal conductivity, such as copper and aluminum.

In the above embodiment, the mounting and connection of the network adapter 100 and the display device 200 are achieved by matching the plurality of heat-dissipation fins 81 and the plurality of matching teeth 221. Compared with the fashion of direct insertion into a USB interface of the display device, the mounting fashion in the present embodiment is more reliable and can effectively prevent the network adapter 100 from detaching from the display device 200.

In addition to limiting relative positions of the network adapter 100 and the display device 200 by the elastic pressing contact between the plurality of heat-dissipation fins and the plurality of matching teeth, in some embodiments, the relative positions of the network adapter 100 and the display device 200 may further limited by the matching the elastic protrusion on the network adapter 100 with a positioning hole on the shell of the display device 200. In some embodiments, the relative positions of the network adapter 100 and the display device 200 may further be limited by the matching the elastic protrusion on the network adapter 100 with the positioning hole on the shell of the display device 200, as well as the elastic pressing contact between the plurality of heat-dissipation fins and the plurality of matching teeth.

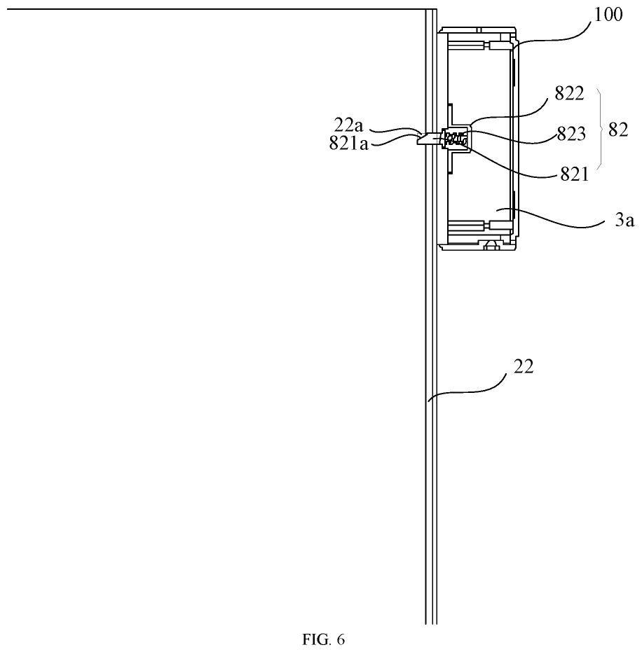

FIG. 6 is a schematic diagram of a matching relationship between the elastic protrusion on the network adapter and the positioning hole on the shell of the display device. As shown in FIG. 6, the display frame 22 is further provided with the positioning hole 22a matched with the elastic protrusion 82, and the positioning hole 22a is disposed in a region between the two adjacent matching teeth 221, proximal to the middle position, of the display frame 22. The elastic protrusion 82 is disposed at a position corresponding to the positioning hole 22a. The elastic protrusion 82 includes a positioning column 821 matched with the positioning hole. The positioning column elastically extends into the positioning hole 22a in the case that the network adapter 100 slides to the assembling position relative to the display frame 22, so as to prevent the network adapter 100 from further sliding on the display frame 22, which plays a role of mounting and positioning. The end portion, proximal to the positioning hole 22a, of the positioning column 821 is provided with an inclined surface 821a. During the movement of the network adapter 100 along a sliding direction, the display frame 22 pushes the positioning column 821 detaching from the positioning hole 22a through the inclined surface 821a, thereby realizing the removal of the network adapter 100 from the display device 200.

Illustratively, the elastic protrusion 82 includes a mounting seat 822, a positioning column 821, and an elastic member 823. The mounting seat 822 is connected to a side wall of the mounting chamber 3a. One end of the positioning column 821 is movably connected to the mounting seat 822, and the other end of the positioning column 821 is provided with the inclined surface 821a and is disposed outside the mounting chamber 3a. The elastic member 823 is disposed between the positioning column 821 and the mounting seat 822 along a telescopic direction of the positioning column 821.

Illustratively, the elastic member 823 is a spring.

In some embodiments, the first connection portion and the plurality of matching teeth 221 have different structures, and the second connection portion and the plurality of heat-dissipation fins 81 have different structures. For example, the first connection portion and the second connection portion may be connection holes connected by a threaded connector, and may further be a buckle structure in buckle connection. For another example, the first connection portion is the display frame 22, and the second connection portion is an elastic clip configured to clamp an edge of the display frame 22.

The above embodiments are described by taking the case where the network adapter 100 is disposed at the display frame 22 as an example, the network adapter 100 may further be disposed at other structural members of the metal shell. For example, the metal shell includes a back cover disposed on the back of the display screen 21. The adapter 100 may be disposed on the back cover.

In the description of the embodiments of the present disclosure, it should be noted that orientation or positional relationships indicated by the terms “center,” “upper,” “lower,” “left,” “right,” “vertical,” “horizontal,” “inner,” “outer,” and the like, are orientation or positional relationships based on the accompanying drawings, and are merely intended to describe the present disclosure and simplify the description, but not indicating or implying specific orientation, and structured and operation in the specific orientation of the described device or element, therefore, should not be constructed as limitations to the present disclosure. Moreover, the terms “first,” “second,” and “third” are merely for the purpose of description and should not be construed as indicating or implying relative importance.

In the description of the present disclosure, unless otherwise specified and limited, it should be noted that the terms “disposed,” “coupled to,” and “connected to” need to be broadly understood, for example, connection may be fixed connection, detachable connection or integrated connection; or may be mechanical connection, or electrical connection; or may be direct connection, or indirect connection via an intermediation, or internal communication of two elements. Those of ordinary skill in the art can understand the specific meaning of the above terms in the present disclosure in accordance with specific conditions.

In addition, the technical features involved in different embodiments of the present disclosure described above may be combined with each other as long as they do not conflict with each other.

The technical solutions of the present disclosure have been described in conjunction with the preferred embodiments shown in the accompanying drawings. However, it is easy for those skilled in the art to understand that the protection scope of the present disclosure is obviously not limited to these specific embodiments. Without departing from principles of the present disclosure, those skilled in the art may make equivalent alterations or substitutions to the relevant technical features, and the technical solutions of these equivalent alterations or substitutions shall fall within the protection scope of the present disclosure.

What is claimed is:

1. A network adapter, comprising: a housing, a communication module, and a thermally conductive member; wherein
the housing is provided with a mounting chamber, wherein the communication module and the thermally conductive member are both disposed in the mounting chamber; and
the housing comprises a metal portion, wherein the metal portion extends from an inner side surface of the housing to an outer side surface of the housing, and the thermally conductive member is in thermal contact with both the communication module and the metal portion.

2. The network adapter according to claim 1, wherein the housing comprises a base and a cover plate; wherein
the cover plate is connected to the base to define the mounting chamber; and
the cover plate is the metal portion, and the base is a plastic base or a metal base.

3. The network adapter according to claim 2, wherein the thermally conductive member is a thermally conductive silicone pad, wherein one side surface of the thermally conductive silicone pad is in contact with the communication module, and the other side surface of the thermally conductive silicone pad is in contact with the cover plate.

4. The network adapter according to claim 1, further comprising a plurality of heat-dissipation fins, wherein the plurality of heat-dissipation fins are disposed on an outer side surface of the metal portion, the outer side surface of the metal portion being a surface, distal from the mounting chamber, of the metal portion.

5. The network adapter according to claim 4, wherein the plurality of heat-dissipation fins are disposed side by side along a first side-by-side direction, and at least one of the plurality of heat-dissipation fins is provided with a first limiting protrusion; wherein the first limiting protrusion protrudes outward from the heat-dissipation fins where the first limiting protrusion is disposed along the first side-by-side direction, and a gap is present between the first limiting protrusion and the outer side surface, disposed between the adjacent heat-dissipation fins, of the metal portion.

6. The network adapter according to claim 1, further comprising an elastic protrusion; wherein the elastic protrusion is connected to the housing, and is configured to extend into a positioning hole of a terminal device in the case that the network adapter slides to an assembling position relative to the terminal device, so as to prevent the network adapter from further sliding.

7. The network adapter according to claim 6, wherein an end portion, proximal to the positioning hole, of the elastic protrusion is provided with an inclined surface; wherein the inclined surface is configured to be matched with the positioning hole to push the elastic protrusion to detach from the positioning hole in a sliding process of the network adapter relative to the terminal device.

8. The network adapter according to claim 7, wherein the elastic protrusion comprises a mounting seat, a positioning column, and an elastic member; wherein
the mounting seat is connected to a side wall of the mounting chamber;
one end of the positioning column is movably connected to the mounting seat, and the other end of the positioning column is provided with an inclined surface and is disposed outside the mounting chamber; and
the elastic member is disposed between the positioning column and the mounting seat along a telescopic direction of the positioning column.

9. The network adapter according to claim 1, wherein the communication module is at least a 4G module or a 5G module.

10. The network adapter according to claim 2, further comprising at least one communication antenna; wherein the communication antenna is connected to the communication module, and the communication antenna is disposed inside the mounting chamber or outside the mounting chamber.

11. The network adapter according to claim 1, further comprising a network transmission device and a circuit board; wherein the communication module and the network transmission device are both connected to the circuit board, and the network transmission device and the circuit board are disposed in the mounting chamber.

12. The network adapter according to claim 11, wherein the housing is provided with a network opening, the network transmission device comprises a network interface, and the network interface is exposed from the network opening.

13. A networking device, comprising a terminal device and a network adapter; wherein
the terminal device is configured to be networked via the network adapter;
the terminal device comprises a metal shell; and
the network adapter comprises: a housing, a communication module, and a thermally conductive member; wherein
the housing is provided with a mounting chamber, and the communication module and the thermally conductive member are both disposed in the mounting chamber, the housing comprises a metal portion, the metal portion extends from an inner side surface of the housing to an outer side surface of the housing, and the thermally conductive member is in thermal contact with both the communication module and the metal portion; and
the housing is connected to the metal shell, and the metal portion is in contact with the metal shell.

14. The networking device according to claim 13, wherein the housing comprises a base and a cover plate; wherein
the cover plate is connected to the base to define the mounting chamber; and
the cover plate is the metal portion, and the base is a plastic base or a metal base.

15. The networking device according to claim 13, wherein
the network adapter further comprises a plurality of heat-dissipation fins; wherein the plurality of heat-dissipation fins are disposed on an outer side surface of the metal portion and are disposed side by side along a first side-by-side direction, and the outer side surface of the metal portion is a surface, distal from the mounting chamber, of the metal portion; and
the metal shell is provided with a plurality of matching teeth disposed side by side; wherein the plurality of matching teeth extend into a lateral side region of the plurality of heat-dissipation fins along the first side-by-side direction, and the plurality of heat-dissipation fins and opposite side surfaces of the plurality of matching teeth are matched in a contact fashion.

16. The networking device according to claim 15, wherein
at least one of the plurality of heat-dissipation fins is provided with a first limiting protrusion; wherein the first limiting protrusion protrudes outward from the heat-dissipation fins where the first limiting protrusion is disposed along the first side-by-side direction, and a gap is present between the first limiting protrusion and the outer side surface, disposed between the adjacent heat-dissipation fins, of the metal portion; and
each of the matching teeth is provided with a second limiting protrusion; wherein the second limiting protrusion and the first limiting protrusion are matched with each other to avoid detaching between the matching teeth and the heat-dissipation fins.

17. The networking device according to claim 16, wherein the matching tooth is made of an aluminum profile.

18. The networking device according to claim 13, wherein a positioning hole is disposed in an outer side wall of the metal shell, the network adapter further comprises an elastic protrusion, and the elastic protrusion is configured to extend into the positioning hole in the case that the network adapter slides to an assembling position, so as to prevent the network adapter from further sliding.

19. The networking device according to claim 18, wherein the elastic protrusion comprises a mounting seat, a positioning column, and an elastic member; wherein
the mounting seat is connected to a side wall of the mounting chamber;
one end of the positioning column is movably connected to the mounting seat, and the other end of the positioning column is provided with an inclined surface and is disposed outside the mounting chamber; and
the elastic member is disposed between the positioning column and the mounting seat along a telescopic direction of the positioning column.

20. The networking device according to claim 13, wherein the terminal device further comprises a display screen, the metal shell comprises a display frame disposed on a periphery of the display screen and a back cover disposed on a back of the display screen, and the network adapter is disposed at the display frame or the back cover.
